(19) United States
(12) Patent Application Publication
(10) Pub. No.: US 2011/0026201 A1
(43) Pub. Date: Feb. 3, 2011

(54) PORTABLE ELECTRONIC DEVICE WITH DUAL KEYPADS

(75) Inventor: KAI XU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/793,743

(22) Filed: Jun. 4, 2010

(30) Foreign Application Priority Data
Jul. 29, 2009 (CN) 200910304961.0

(51) Int. Cl. H05K 7/00

(52) U.S. Cl. 361/679.01

(57) ABSTRACT

A portable electronic device includes a main body, a hinge assembly and a display assembly. The main body includes a first keypad at one side and a second keypad at another side. The display assembly is rotatably attached to the main body by the hinge assembly. The first keypad is used when the display assembly rotates to a same side of the main body as the first keypad. The second keypad is used when the display assembly rotates to a same side of the main body as the second keypad.

### BACKGROUND

1. Technical Field

The present disclosure relates to portable electronic devices, particularly, to a portable electronic device with keypads.

2. Description of Related Art

Keypads are widely used in portable electronic devices (e.g., mobile phones and personal digital assistants) for facilitating various user operations. Nowadays, portable electronic devices generally have game functions. However, the keys of the typical keypad are usually too small and not practical for playing games.

Therefore, there is room for improvement within the art.

### BRIEF DESCRIPTION OF THE DRAWINGS

Many aspects of the portable electronic device can be better understood with reference to the following drawings. The components in the drawings are not necessarily drawn to scale, the emphasis instead being placed upon clearly illustrating the principles of the portable electronic device.

FIG. 1 is a partially exploded, isometric view of a portable electronic device, in accordance with an exemplary embodiment.

FIG. 2 is similar to FIG. 1, but shown from another aspect.

FIG. 3 is an assembled, isometric view of the portable electronic device of FIG. 1, showing a display assembly of the portable electronic device positioned at a first state.

FIG. 4 is similar to FIG. 3, but showing the display assembly of the portable electronic device positioned at a second state.

FIG. 5 is a cross-sectional view of the assembled portable electronic device along line V-V shown in FIG. 4, in accordance with another exemplary embodiment.

### DETAILED DESCRIPTION

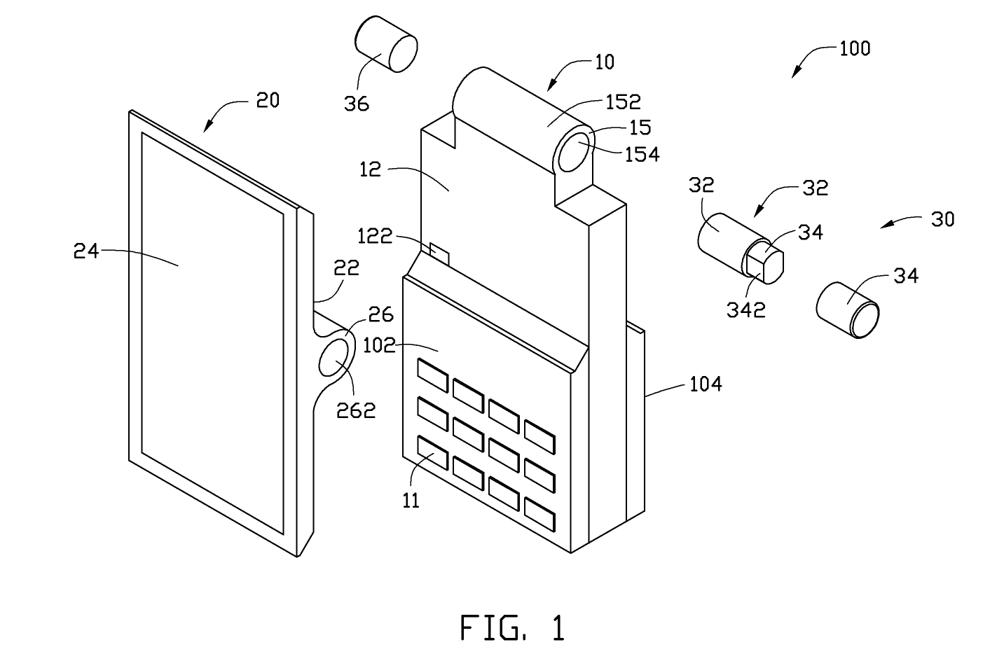

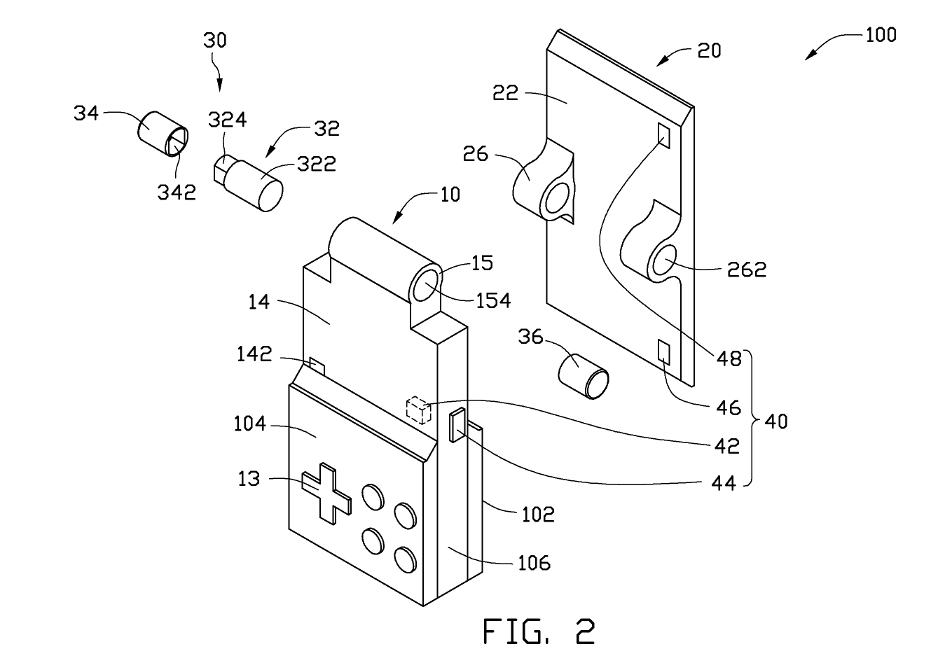

FIG. 1 shows an exemplary embodiment of a portable electronic device 100. Also referring to FIG. 2, the device 100 includes a main body 10, a display assembly 20, a hinge assembly 30, and a locking structure 40. The display assembly 20 is rotatably attached to the main body 10 by the hinge assembly 30, and is locked to the main body 10 by the locking structure 40.

The main body 10 includes a first surface 102, a second surface 104 and a sidewall 106 connecting the first surface 102 and the second surface 104. One end of the first surface 102 is recessed to form a first receiving portion 12, and the second surface 104 is correspondingly recessed to form a second receiving portion 14. A first keypad 11 is fixed on the first surface 102 adjacent to the first receiving portion 12, and a second keypad 13 is fixed on the second surface 104 adjacent to the second receiving portion 14. In this exemplary embodiment, the first keypad 11 is used for messaging functions, such as calling, receiving, or text messaging, and the second keypad 13 is used as a game controller to play games. The first and second receiving portions 12 and 14 respectively have a first switch 122, a second switch 142 fixed at one end thereof. The first and second switches 122 and 142 may be, e.g., mechanical, optical, or hall-effect switches and are correspondingly used to activate the first and second keypads 11 and 13. A barrel 15 is formed at one end of the first and second receiving portions 12 and 14, which defines a shaft hole 154 for receiving the hinge assembly 30.

The display assembly 20 includes a display screen 24 at one side thereof and a support board 22 at the other side thereof. Two knuckles 26 are correspondingly formed at the two sides of the support board 22. Each knuckle 26 defines a receiving hole 262 for engaging with the hinge assembly 30.

The hinge assembly 30 includes a first shaft 32, a second shaft 34, and a third shaft 36. The first shaft 32 includes a fixing portion 322 and a latching portion 324 connected to each other. The fixing portion 322 is cylindrical and snugly fixed in the shaft hole 154 when assembled. The second shaft 34 defines a latching hole 342 for receiving the latching portion 324 of the first shaft 32 so that the second shaft 34 can rotate in sequence with the first shaft 32.

In this exemplary embodiment, the locking structure 40 includes an electromagnet 42, a button 44, a first magnet 46, and a second magnet 48. The electromagnet 42 is fixed inside the main body 10. The button 44 is fixed on the sidewall 106 of the main body 10, for changing the magnetic polarity of the electromagnet 42. The two magnets 46 and 48 are respectively fixed on the support board 22 at two ends, corresponding to the electromagnet 42 of the main body 10.

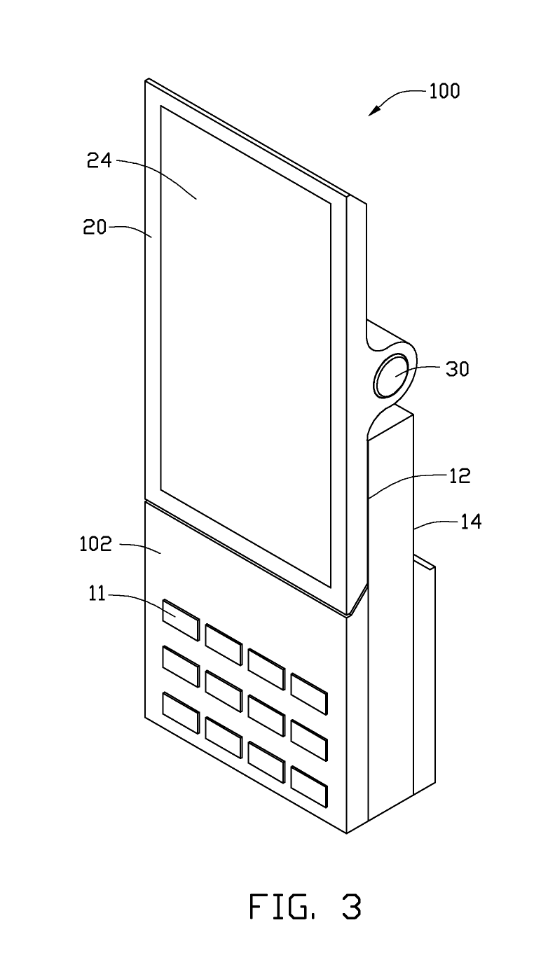

Also referring to FIG. 3, to attach the display assembly 20 to the main body 10, the fixing portion 322 of the first shaft 32 is fixed in the shaft hole 154 of the barrel 15 at one end. One end of the second shaft 34 is rotatably received in the receiving hole 262 of one knuckle 26. The third shaft 36 is partially and rotatably received in the receiving hole 262 of the other knuckle 26. The latching portion 324 of the first shaft 32 is received in the latching hole 342 of the second shaft 34, and another end of the third shaft 36 is rotatably received in shaft hole 154 of the barrel 15 at another end. Thus, the display assembly 20 can rotate relative to the main body 10 by the hinge assembly 30.

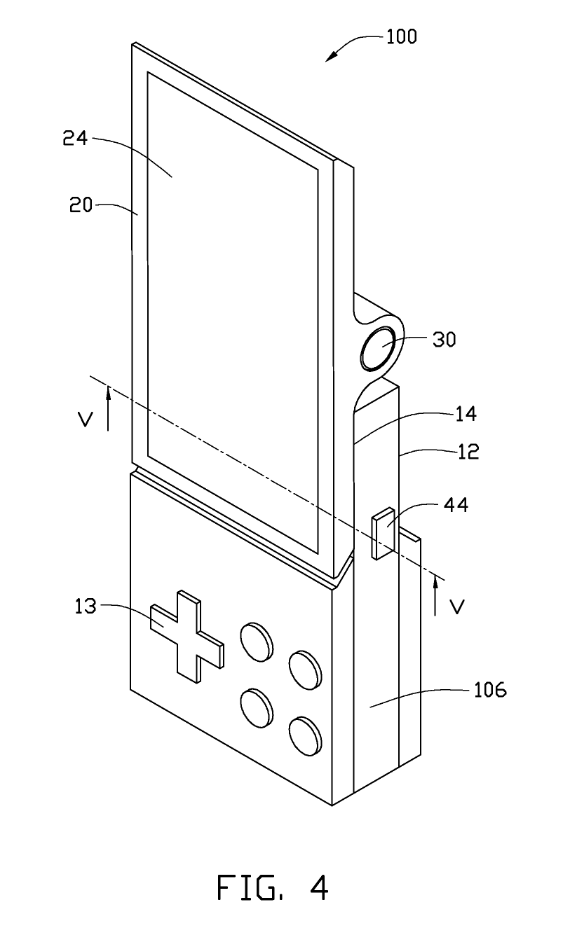

In use, the display assembly 20 may be rotated to the first receiving portion 12 so that the display screen 24 and the first keypad face the same direction, i.e., towards the user. The first magnet 46 is attracted by the electromagnet 42, so that the display assembly 20 is locked to the main body 10. At which time, the display assembly 20 activates the first switch 122 to activate the first keypad 11. When the user wants to play games, the button 44 is used to change the magnetic polarity direction of the electromagnet 42, which makes the lock between the display assembly 20 and the main body 10 disappear as well as create a repelling force. Referring to FIG. 4, the display assembly 20 is rotated to the second receiving portion 14 so that the display screen 24 and the second keypad face the same direction, i.e., towards the user and is locked to the main body 10 by attraction between the second magnet 48 and the electromagnet 42. At the same time, the display assembly 20 activates the second switch 142 to activate the second keypad 13.

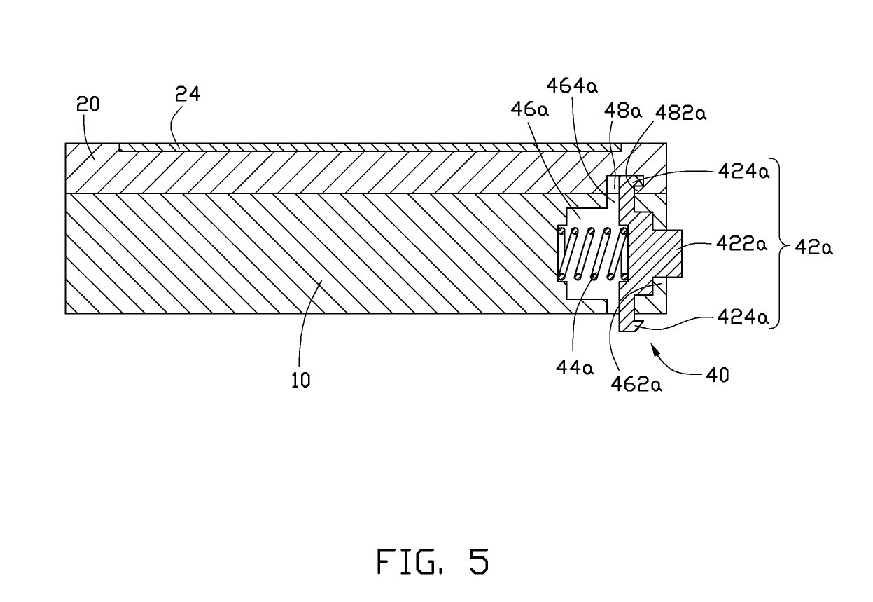

Referring to FIG. 5, in another exemplary embodiment, the locking structure 40a includes a button 42a, a spring 44a, a cavity 46a defined in the main body 10, and two locking holes 48a respectively defined at two ends of the support board 22 of the display assembly 20. The button 42a includes an operating portion 422a and two hooks 424′. A through hole 462a is defined in the sidewall 106, communicating with the cavity 46a. An extending hole 464a communicating with the cavity 46a is respectively defined in the first, second receiving portions 12 and 14. respectively define an extending hole 464a communicating with the cavity 46a. The button 42a is received in the cavity 46a. The operating portion 422a extends through the through hole 462a, and the two hooks 424′ respectively extend through the extending holes 464a. The spring 44a is fixed in the cavity 46a and resists the button 42a. The locking holes 48a allow the corresponding hooks 424a to slide. A protrusion 482a extends over each locking hole 48a for locking the hooks 424a. When the display assembly 20 is rotated to the first/second receiving portion 12 or 14, the button 42a is pressed down and the hook 424a is received in the locking hole 48a. At the same time, the spring 44a is deformed. The pressure applied on the button 42a is then released, and the spring 44a returns to its original shape to push the button 42a to its original position. Thus, the hooks 424a are locked by the protrusion 482a.

It is to be understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable electronic device comprising:
a main body having first and second sides and including a first keypad on the first side and a second keypad on the second side;
a hinge assembly; and
a display assembly, the display assembly being rotatably attached to the main body by the hinge assembly, the display assembly rotated to one side of the main body to allow the first keypad or the second keypad face the same direction as the display assembly.

2. The portable electronic device as claimed in claim 1, wherein the main body including a first receiving portion and a second receiving portion for selectively and partially receiving the display assembly, the first receiving portion is positioned at a same side of the main body as the first keypad, and the second receiving portion is positioned at a same side of the main body as the second keypad.

3. The portable electronic device as claimed in claim 2, wherein a first switch is fixed in the first receiving portion, and when the display assembly rotates to the first receiving portion, the first switch is activated by the display assembly to activate the first keypad.

4. The portable electronic device as claimed in claim 2, wherein a second switch is fixed in the second receiving portion, and when the display assembly rotates to the second receiving portion, the second switch is activated by the display assembly to activate the second keypad.

5. The portable electronic device as claimed in claim 1, further comprising a locking structure, wherein the locking structure selectively lock the display assembly to the main body at one of the two sides of the main body according to which keypad is being used.

6. The portable electronic device as claimed in claim 5, wherein the locking structure includes an electromagnet in the main body and two magnets at two ends of the display assembly, and the display assembly is locked to the main body by the attraction between one of the two magnets and the electromagnet.

7. The portable electronic device as claimed in claim 6, wherein the locking structure further includes a button, the main body includes a sidewall, and the button is fixed on the sidewall of the main body for changing the magnetic polarity of the electromagnet.

8. The portable electronic device as claimed in claim 5, wherein the locking structure includes two hooks at two sides of the main body correspondingly, the display assembly defines two locking holes at two corresponding ends, and the hook is engaged in the corresponding locking hole to lock the display assembly in position relative to the main body.

9. The portable electronic device as claimed in claim 8, wherein the locking structure further includes a button and a spring, the hooks are portions of the button, the main body defines a cavity receiving the spring and the button, and the spring resists the button.

10. The portable electronic device as claimed in claim 9, wherein the main body includes a sidewall and defines a through hole in the sidewall communicating to the cavity, the button includes an operating portion extending through the through hole, and the main body defines two corresponding extending holes communicating to the cavity allowing the hooks to extend through.

11. The portable electronic device as claimed in claim 9, wherein the main body defines a shaft hole at one end, the display assembly includes two bearings, and the hinge assembly engaged in the shaft hole and the bearings.

12. A portable electronic device comprising:
a main body including a first keypad and a second keypad at two opposite sides correspondingly, two switches, each switch being positioned on a same side of the main body as the first keypad and the second keypad; and
a display assembly, the display assembly being rotatably attached to the main body, the display assembly selectively activating one of the two switches to activate the first keypad or the second keypad.

13. The portable electronic device as claimed in claim 12, wherein the main body including a first receiving portion and a second receiving portion for selectively and partially receiving the display assembly, and the two switches are correspondingly fixed in the first receiving portion and the second receiving portion.

14. The portable electronic device as claimed in claim 12, further comprising a locking structure, wherein the locking structure selectively lock the display assembly to the main body at one of the two sides of the main body according to which keypad is being used.

15. The portable electronic device as claimed in claim 14, wherein the locking structure includes an electromagnet in the main body and two magnets at two ends of the display assembly, and the display assembly is locked to the main body by the attraction between one of the two magnets and the electromagnet.

16. The portable electronic device as claimed in claim 15, wherein the locking structure further includes a button, the main body includes a sidewall, and the button is fixed on the sidewall of the main body for changing the magnetic polarity of the electromagnet.

17. The portable electronic device as claimed in claim 14, wherein the locking structure includes two hooks at two sides of the main body correspondingly, the display assembly defines two locking holes at two ends correspondingly, and the hook is engaged in the corresponding locking hole to lock the display assembly to the main body.

18. The portable electronic device as claimed in claim 17, wherein the locking structure further includes a button and a spring, the hooks are portions of the button, the main body defines a cavity receiving the spring and the button, and the spring resists the button.

19. The portable electronic device as claimed in claim 18, wherein the main body includes a sidewall and defines a through hole in the sidewall communicating to the cavity, the button includes an operating portion extending through the through hole, and the main body defines two extending holes communicating to the cavity allowing the hooks to extend through correspondingly.

20. The portable electronic device as claimed in claim 18, further comprising a hinge assembly, wherein the main body defines a shaft hole at one end, the display assembly includes two bearings, and the hinge assembly engaged in the shaft hole and the bearings.
